(19) United States
(12) Patent Application Publication
(10) Pub. No.: US 2023/0048216 A1
(43) Pub. Date: Feb. 16, 2023

(54) MEMS Vibrating Ring Resonator with Deformable Inner Ring-Shaped Spring Supports

(71) Applicant: UNIVERSITY OF WINDSOR, Windsor (CA)

(72) Inventors: Imran KHAN, Missisauga (CA); David S.K. Ting, LaSalle (CA); Mohammed Jalal Ahamed, Windsor (CA)

(73) Assignee: UNIVERSITY OF WINDSOR

(21) Appl. No.: 17/393,451

(22) Filed: Aug. 4, 2021

(51) Int. Cl. H03H 9/24; H03H 9/02; G01C 19/5684; B81B 7/02

(52) U.S. Cl. CPC H03H 9/2431; H03H 9/02338; G01C 19/5684; B81B 7/02; H03H 2009/02346; B81B 2201/0242

(57) ABSTRACT

A Microelectromechanical systems (MEMS) based ring resonator includes an outer ring which is supported in resilient deformable movement relative to one or more peripherally disposed electrodes by a symmetrically positioned array of radially extending inner spring supports. The inner spring supports extend radially from a central anchor post or support to the inner circumferential edge of the outer ring. The innerspring supports are configured to deformation or regulate movement in outer ring driving and sensing modes.

### SCOPE OF THE INVENTION

The present invention relates to a vibrating ring resonator, and more particularly a ring resonator having an outer ring which is supported in resiliently deformable and/or oscillating and/or movement along its interior radial surface by a series of radially spaced, resiliently deformable spring members which are preferably formed having a closed geometric shape.

### BACKGROUND OF THE INVENTION

Micromechanical Microelectromechanical Systems (MEMS) based gyroscopes are miniature versions of vibratory gyroscopes used to detect direction and rotational velocity in three axis. Different types of vibratory gyroscopes include string vibratory, cubical mass vibratory, ring vibratory, spherical, and wine glass vibratory gyroscope constructions. Vibrating gyroscopes may further be classified by their degenerate and non-degenerate mode shapes generated by vibrating ring movement. If more than one mode shape is generated at the same resonance frequency, mode shapes are called degenerate, while the generation of only one mode shape at resonance frequency is non-degenerate. Degeneracy is based on symmetric and non-symmetric structure design. In gyroscope design, degenerate mode shapes are frequently used to identify the driving and sensing mode shapes at the same frequency. Different mode shapes are possible to fulfill the requirements of gyro sensors; however, research shows that wine glass mode shapes may enable high-performance, dynamic MEMS devices due to potential advantages in symmetry structure, low energy loss, and ability to counterbalance external vibrations.

MEMS based gyroscopes have been developed to sense out-of-plane motion using principles of electrostatic repulsion force or an out-of-plane sensing and driving butterfly resonators. A three-axis micro gyroscope with a vibrating ring has demonstrated in-plane and out-of-plane driving and sensing mechanisms by Y. Jeon, H. Kwon, H. C. Kim and S. W. Kim, “Design and development of a 3-axis micro gyroscope with vibratory ring springs.” in EuroSensors 28th Conference, Korea, 2014.

Gyroscopes with a circular mass and ring vibrating structures have also been considered because of the symmetrical structure provided. A dual-axis disk gyroscope, with disk operation based on the design of a circular inertial rotor with a symmetrical quad is described in T. Juneau. A. Pisano and J. Smith, “Dual axis operation of a micromachined rate gyroscope in Solid state sensors and actuators,” in TRANSDUCERS '97 International conference, IEEE, pp 883-886, Chicago, 1997. A vibrating wheel gyroscope disclosed in D. Yuqian, G. Zhongyu, Z. Rong and C. Zhiyong, “A Vibrating Wheel Micromachined Gyroscope for Commercial and Automotive Applications,” Proceedings of the 16th IEEEF Instrumentation and Measurement Technology Conference (Cat. No. 99CH36309), 1999, Vol. 3, pp. 1750-1754 has a vibrating ring as its proof mass, with four crossed slight beams attached to the center node.

Vibrating ring gyroscopes (VRGs), in which the ring is connected with a solid anchor have been suggested by P. Greiff, “A vibratory micromechanical gyroscope,” in AIAA guidance and control conference, Minneapolis, Minn. USA, 1988. Greiff, supra, describes the vibrating ring gyroscopes as developed using a nickel electroplating method, resulting in a resonance frequency of 33 kHz, sensitivity of 10 mv/°/sec and low Q-factor of 2000. Subsequently, a similar design was developed using polysilicon, which provided a higher Q-factor (40,000) with a calculated resonance frequency of 33 kHz (see F. Ayazi and K. Najafi, “Design and Fabrication of A High-Performance Polysilicon Vibrating Ring Gyroscope,” in IEEE, Heidelberg, Germany, 1998). The design was further modified with a high aspect ratio (width of 4 μm and thickness of 80 μm) capable of producing degenerate flexural mode frequency at 29.28 kHz with a 0 Hz split frequency, but a low sensitivity of 0.2 mv/°/sec, (see F. Ayazi and K. Najai, “A HARPSS Polysilicon Vibrating Ring Gyroscope,” Journal of Micromechanical Systems, vol. 10, no. 2, pp. 169-179, 2001). To improve the sensitivity, a single crystal silicon was used to develop the same design of gyro on a glass substrate, resulting in sensitivity of 132 mv/°/sec, with a measured resonance frequency of 26.36 kHz (see H. Guohong and N. Khalil. “A SINGLE-CRYSTAL SILICON VIBRATING RING GYROSCOPE.” Dig. Tech. Papers, A Solid State Sensors, Actuators and Microsystems Workshop (HiltonHead), pp. 718-721, 2002). The stiffness of the support spring was estimated based on the variable time stiffness of the ring, with the variable ranging from 5 to 6.4, and then 7.4, which contradicts the estimation of stiffness values. This ambiguity was resolved by an analysis of the relationship between the spring stiffness and the ring stiffness by S. Wei and W. Xuemin, “A new calculation of potential energy of supporting springs and the application in design of vibrating ring gyroscope.” Aerospace Science and Technology, vol. 15, no. 1, pp. 409-415, 2011. Another VRG, with a U-shaped support spring using a solid anchor has been described by Z. Kou, J. Liu, H. Ca, H. Feng, J. Ren, Q. Kang and Y. Shil, “Design and Fabrication of a Novel MEMS vibrating ring Gyroscope,” in IEEE. Beijing, China, 2017, with splitting frequencies of 46 Hz, and 184 Hz with and without electrical compensation, respectively.

The inventors have appreciated that VRGs have unique features not found in other vibratory gyroscopes, such as a balanced symmetrical structure leading to identical flexural mode shapes, which result in high sensitivity and nominally equal resonance frequencies in driving and sensing modes. The ring vibratory structure is also less temperature-sensitive than other vibratory gyroscopes and supports electrical tuning to improve its performance.

For example, performance and sensitivity of VRGs may be improved by using an electrical control system. Electrical filters and noise compensatory circuits may be used for tuning and matching the frequencies of the driving and sensing modes (see for example B. Eminoglu, S. E. Alper and T. Akin, “An Optimized Analog Drive-Mode Controller for Vibratory MEMS Gyroscopes,” in Elsevier, Athens, Greece, 2011). However, methods of electrical compensation have not proven reliable in all operating conditions, and have a limited range of operations.

The n-type doping of silicon material has been considered to reduce the temperature coefficient of frequency and improve the performance of resonator. To date, the doping range has proven limited. Improvement of the mechanical design of the oscillating ring has also been suggested, however heretofore, proposed designs have been complex, making them difficult to fabricate and more susceptible to the influence of the environment due to vibratory movement within the ring.

### SUMMARY OF THE INVENTION

The present invention seeks to provide a vibrating or oscillating ring resonator which has a simplified structure selected to provide sensitivity and performance, without requiring a separate electrical compensation circuitry. In one embodiment, the ring resonator may be provided as part of a VRG.

In a non-limiting construction, VRG may have a simple geometric shape, having a circular outer ring which is adapted for oscillatory and/or resilient deformation movement due to electrostatic and Coriolis forces relative to one or more surrounding or adjacent electrode structures. The outer ring is most preferably concentrically disposed about a fixed central stein or anchor post. A plurality preferably between three and twelve, and most preferably four, six, eight or ten spring supports resiliently support the outer ring in resilient deformation and/or vibratory or oscillatory movement relative to both the adjacent electrode structures and central anchor post.

Although not essential, to facilitate premanufacturing with a selected VGR sensitivity, in one possible embodiment, the spring supports are preferably provided having substantially the identical geometric profile and configuration. More preferably, the spring supports are arranged in a radial array so as to extend radially outwardly about a central axis of the anchor post, spaced at substantially equally spaced distances from each other. Although not essential, preferably the ring supports and outer ring are provided in a substantially coplanar suspended arrangement, integrally formed with the center anchor post.

In one embodiment, the spring supports preferably extend radially from the anchor post to the inner peripheral surface of the outer ring. The spring supports provided with a resiliently deformable compressible shape which is selected to allow for the desired degree and sensitivity of the VGR and resilient deformation and/or oscillatory movement of the outer ring relative to the central anchor and/or surrounding electrodes structures as the VGR is moved. The outer ring itself may have a sidewall thickness and construction selected to allow for its resilient deformation from a circular rest shape. Preferably, the outer ring and support springs are configured whereby the outer ring is movable from a rest orientation, where the outer ring assumes an orientation concentric about and spaced a constant radial distance from the anchor post axis. On the application threshold extension forces, and most preferably predetermined threshold forces at least part of the outer ring moves from the rest position to a position spaced a differing radial distance towards or away from the anchor post axis, as the outer ring oscillates or deforms.

Although not essential, the spring supports most preferably have a closed geometric shape and resiliently bias the outer ring towards the rest position. Although not essential, the spring supports most preferably are formed symmetrically about a respective, radially extending spring axis. In non-limiting embodiments, the closed geometric shape of the spring supports is selected from generally an ellipse, an oval, a parabola, a vesica piscis, or most preferably, a circle.

In one simplified construction, three to twelve, and preferably four, six or eight spring supports are arranged in a petal-shaped configuration about the central anchor post. To facilitate manufacturing and pre-tuning of VGRs, each spring support preferably has the identical geometric shape and/or size, spanning laterally from the central anchor post to the inner radial surface of the outer ring. It is to be appreciated however, that individual spring supports having different geometries and/or spring supports arranged with different symmetries may also be used, depending on the desired VRG oscillation characteristics.

The closed geometric shape of support springs is preferably provided as a shape selected to provide control over the stiffness and the desired mode shapes of the VRG. Geometric elements, such as the spring supports and/or outer ring shape and dimensions are most preferably chosen with mathematically reproducible geometric properties to allow finite element modeling techniques. This may more easily pre-tailor the sensitivity of ring resonators for use in a variety of applications, including MEMS gyroscope prior to production and/or to allow for simplified post manufacture tuning using suitable electrical control systems. It is further recognized that resonance frequencies for different mode shapes may be achieved by changing the parameters of the proposed spring support/outer ring structures. In one non-limiting embodiment, a MEMS gyroscope according to the invention may operate with degenerate mode shapes (with 0 Hz frequency splitting) at resonance frequencies in the range of 25 kHz to 74 kHz, controlled by increasing the spring support and outer ring structure width from 10 pun to 30 μm.

In another non-limiting embodiment, the vibrating ring resonator may be provided for use in accelerometers, gyroscopes or other similar applications. The ring resonator includes a vibrating or oscillating outer ring which is mounted for vibratory movement relative to a central anchor post and one or more surrounding electrodes by way of a plurality of vesica piscis shaped or circular spring supports. The outer ring further may be resiliently deformable. More preferably, the spring supports are provided with a generally circular or ring shape and are arranged about the central anchor post in a cauliflower arrangement. The outer ring, spring supports, and central anchor post geometries are most preferably selected such that the circular ring-shaped spring supports are formed having a spring support diameter selected at between about 0.2 to about 0.45, and preferably about 0.25 to about 0.4 times the diameter of the outer ring. Although not essential, for simplified manufacture and pre-production modelling, each of the spring supports and outer ring are preferably formed having substantially the same sidewall dimensions and flexure properties.

In another embodiment, the outer ring is mounted for resilient deformation and/or oscillatory or vibratory movement relative to one or more peripherally disposed electrodes. Each of the electrodes formed having a generally arcuate, proximal facing surfaces which have substantially the same radius of curvature as the outer ring.

The ring resonator may be manufactured with an outer ring size and/or dimension selected to provide a target range of model frequency and minimize the difference between the drive and sense frequencies.

In the publication by 1. Khan., D, ring, and M. Ahamed entitled “Design and development of a MEMS vibrating ring resonator with inner rose petal spring supports”, Microsystem Technologies (2021) 27; 985-995, published 18 Aug. 2020, the contents of which are incorporated herein by reference in their entirety, the inventors describe an alternative non-limiting embodiment, in which the spring supports are provided with a closed geometric, generally vesica piscis shape and are arranged in a rose petal configuration. Particularly, the vibrating ring resonator may be provided with four radially spaced and equal sized lens or vesica piscis-shaped spring supports, which span radially outwardly from the central anchor post to supportingly engage the inner periphery of the outer ring.

In the assembly, resilient deformation of the inner ring spring supports is selected for substantially free movement of the outer ring relative to the electrodes while remaining attached and anchored to the middle support anchor structure under threshold electrostatic, Coriolis forces, acceleration/deceleration and/or gravitational forces.

The present invention may reside in various non-limiting aspects, and which include without limitation the following: In a first aspect, a vibrating ring resonator assembly comprising, a central support anchor having an anchor axis, an annular outer ring member, at least one electrode structure spaced radially about at least part of the outer ring member, a plurality of resiliently deformable spring supports supporting said outer ring member in oscillatory and % or deformation movement relative to said central anchor and said at least one electrode structure, whereby movement of the outer ring member relative to said at least electrode is structure is configured to generates an electrical signal, the spring supports configured to resiliently bias said outer ring to return to substantially circular undeformed geometry concentric with said anchor axis under forces selected less than predetermined threshold force.

In another aspect, a gyroscope ring resonator comprising, a ring resonator including, a central support having a support axis, an outer ring member disposed radially about the support axis, the outer ring member having an outer peripheral surface and an inner peripheral surface spaced radially towards the support axis, a plurality of spring supports interposed between said central support and said inner peripheral surface, the spring supports comprising a closed geometric body and supporting said outer ring member in at least one of oscillatory and deformable movement relative to said central support, whereby the application of a predetermined threshold force, the outer ring member being configured for movement from a rest orientation extending concentrically about said support axis with a substantially constant radial distance from said support axis, and a deformed orientation wherein portions of the outer ring member are moved to differing radial distances from said support axis, the spring supports resiliently biasing the outer ring member towards the rest orientation.

In a further aspect, a vibrating ring resonator assembly comprising: a support anchor having a central anchor axis, a circular outer resonator ring having an outer peripheral surface and an inner peripheral surface, an electrode structure disposed radially outwardly from a least part of the outer peripheral surface from four to eight spring supports coupling the outer resonator ring to the support anchor, the spring supports spanning radially from the support anchor to the inner peripheral surface and having a substantially closed geometric shape selected from the group consisting of a circle, an ellipse, an oval and vesica piscis, each spring support being symmetrical about an associated radially extending spring axis, the spring axis of the spring supports being disposed at substantially equally spaced locations about the central anchor axis, and wherein the spring supports support the outer resonator ring in deformable and/or oscillatory movement relative to said electrode structure on the application of a threshold force.

### BRIEF DESCRIPTION OF THE DRAWINGS

Reference may now be had to the following detailed description taken together the accompanying drawings in which:

FIG. 1 illustrates schematically a MEMS gyroscope incorporating a vibrating ring resonator in accordance with a preferred embodiment of the invention;

FIG. 2 illustrates schematically, in plan view a vibrating ring resonator assembly in accordance with a preferred embodiment, and which incorporates an outer ring supported for resilient deformation and oscillatory vibratory movement by four circular spring supports attached to a solid central anchor post;

FIG. 3 shows an enlarged partial view of the vibrating resonator assembly of FIG. 2;

FIG. 4 illustrates a cross-sectional view of a vibrating ring resonator assembly shown in FIG. 3, taken along line 4-4¹;

FIG. 5 illustrates schematically a perspective view showing the outer ring, spring supports and central anchor post used in the vibrating ring resonator assembly shown in FIG. 2;

FIGS. 6a, 6b and 6c illustrate schematically, the oscillation and deformation of the outer ring used in the vibrating ring resonator of FIG. 2, on the application of threshold vibratory or Coriolis or acceleration forces thereto;

FIG. 7 shows the embodiment of the inventor (published in August 2020) in which the spring supports are provided with a closed geometric, generally vesica piscis shape and are arranged in a rose petal configuration.

FIGS. 8a to 5c illustrate graphically the relationship between spring stiffness and support spring thickness, width and diameter spacing of the embodiment (FIG. 7);

FIGS. 9a and 9b illustrate graphically the relationship between sensor mechanical sensitivity, sensor quality function (Q) and resonance frequency of the embodiment (FIG. 7);

FIGS. 10a-10e illustrate schematically, a process for the photo resist deposition manufacture of the vibrating ring resonator used in the vibrating ring resonator assembly shown in FIG. 2 and FIG. 7;

FIGS. 11a and 11b show the SEM (scanning electron microscope) images of the embodiments shown in FIG. 2 (Ring spring resonator) and FIG. 7 (lens/petal shape spring resonator)

FIGS. 12a and 12b illustrate graphically an exemplary resonator frequency response of the embodiments shown in FIG. 2 and FIG. 7 respectively, illustrating the resonance frequency of a prototype ring resonator assembly according to the invention; and

FIGS. 13A, and 13B illustrate schematically oscillating ring, spring support and central anchor post constructions for use in the vibrating ring resonator assembly, in accordance with alternative embodiments of the invention.

### DETAILED DESCRIPTION OF THE PREFERRED EMBODIMENTS

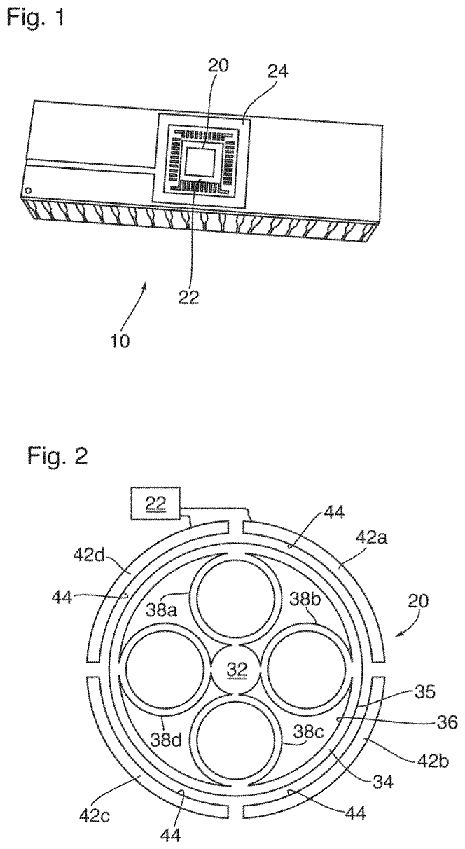

Reference may be had to FIG. 1 which illustrates a MEMS gyroscope 10 suitable for use in vehicles, hand-held personal electronic devices and/or other, in accordance with a preferred embodiment of the invention. As will be described, MEMS gyroscope 10 incorporates a vibrating ring resonator assembly 20, in accordance with a preferred embodiment of the invention. The vibrating ring resonator assembly 20 surrounded by electrodes which are connected with electrical pads 22 mounted on 40 DIP (Dual in-line package) chip 24 to provide electrical control features using driving and sensing circuits.

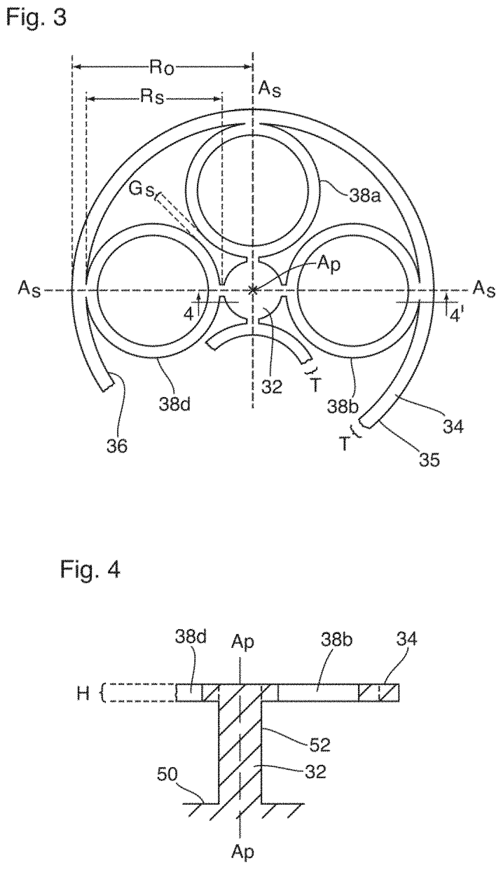

FIG. 2 shows best the vibrating ring resonator assembly 20 as including a solid cylindrical central anchor support 32, fixedly mounted to a substrate 50 (FIG. 4) a resiliently deformable outer ring 34, and four resiliently deformable circular ring-shaped spring supports 38a,38b,38c,38d, which as will be described, function as resiliently compressible springs. FIG. 2 shows the outer ring 34 having a constant sidewall thickness T with a substantially parallel and inner peripheral surfaces 35,36. In a resting undeformed state the outer ring 34 has a circular shape, extending concentrically about and centered on the central anchor post axis Ap. In the undeformed state shown in FIG. 2, each of the ring-shaped spring supports 38a,38b,38c,38d resiliently assume a circular configuration. The spring supports 38 extend radially from the outer peripheral surface 52 (FIG. 4) of the anchor post 32, and have a radial diameter selected to span between the anchor post 32 and the inner radial surface 36 of the outer ring 34. FIGS. 2 and 3 show best each of the spring supports 38 as being centered on and symmetrically formed about a respective radial support axis Aₛ which each converge to intersect at a center axis Aₚ of the anchor post axis. The adjacent radial support axis A, of the spring supports 38a-38d are oriented at 90′ and equally spaced from each other, providing the spring supports 38a,38b,38c,38d as a radial array extending at radially equally spaced locations about the anchor post axis Aₚ.

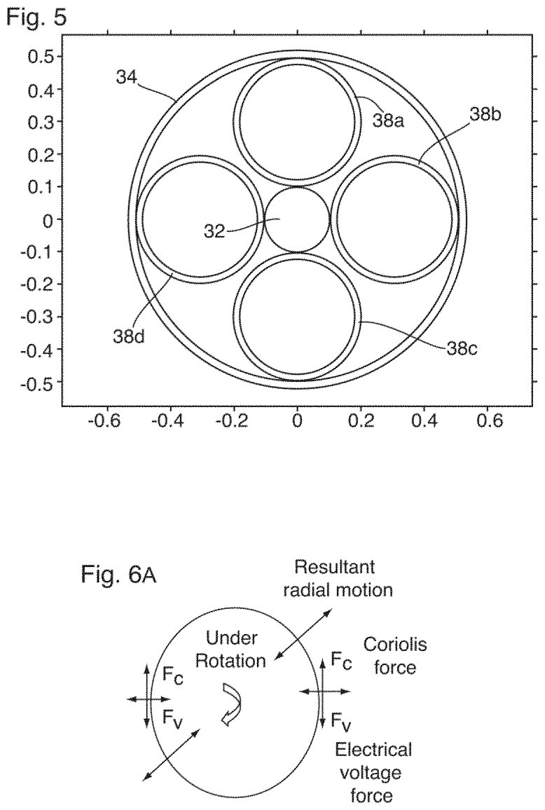

FIG. 2 shows best, the outer ring 34, spring supports 38a,38b,38c,38d and central anchor post 32 as being integrally formed, and in a preferred mode of manufacture, the outer ring 34, spring supports 38 and central anchor post 32 are formed by plasma deposition process. In a preferred construction, the spring supports 38a,38b,38c,38d have a radial diameter selected at between about 0.2 and 0.45, and preferably 0.2 and 0.4 times the radial diameter Rₒ of the outer ring 34. In the use of the MEMS gyroscope 10. FIG. 5 shows the outer ring 34 has a radial outermost diameter selected at between about 500 μm to 1500 μm, and preferably about 1200 μm. The outer radial diameter of each of the circular spring supports 38 is preferably selected at between about 200 μm to about 600 μm, and most preferably about 400 μm; and wherein the anchor post 32 has a cross sectional diameter of between about 100 μm and 300 μm. Different relative diameters may however be provided, depending on the number and/or geometric shape of the particular spring supports 38 used and intended gyroscope application.

Although not essential, preferably outer ring 34 and each of the ring-shaped spring supports 38a,38b,38c,38d have a lateral width thickness T selected at between about 5 and about 50 μm preferably about 10 to 30 μm; and a vertical height H of between about 10 to about 100 μm, and preferably about 30 μm to about 80 μm. Other widths and/or thickness may however be used, depending on desired resonator assembly properties. The relative sizing advantageously provides a minimum gap spacing (Gₛ) of between about 5 μm and 50 μm, preferably about 10 μm, between adjacent pairs of spring supports 38. This gap spacing (Gₛ) advantageously allows initially the unrestricted deformation of the spring supports 38 together the outer ring 34 under a preselected threshold Coriolis, acceleration deceleration and/or inclination or gravitational forces. The gap spacing (Gₛ) and contact between adjacent spring supports 38 may however limit excess deformation of the outer ring 34 and/or spring supports 38 on the occurrence of high shock effects. The final width and % or thickness are selected to allow a predetermined freedom of deformation and movement of the outer ring 34 under predetermined Coriolis, vibratory, acceleration, deceleration and/or gravitational inclination forces. FIG. 2 further illustrates the resonator assembly 20 as including four electrodes 42a,42b,42c,42d connected with electrical pads 22. The electrodes 42a-d are positioned radially about the outer ring 34. Each of the electrodes 42 preferably includes a respective radially extending proximate surface 44. The proximate surfaces 44 of the electrodes 42a-d are oriented closest towards and are spaced a distance from the outer ring 34. Preferably, the proximate surfaces 44 are and are provided with a radius of curvature substantially corresponding to the curvature of the outer surface 35 of the outer ring 34. As will be described, the electrodes 42a-42d are used with outer ring 34 for MEMS gyroscope driving and sensing.

As will be described, the outer ring 24 and spring supports 38a,38b,38c,38d are configured whereby the application of a predetermined electrostatic force in the gyroscope 20 effects relative movement and/or displacement of portions of the outer ring 34 relative to one or more of the proximate surfaces 44 of the associated electrode 42a,42b,42c,42d. As portions of the outer ring 34 move relative to the electrodes 42a-42b electric signals are generated and transmitted by the electrical pads 22 to the electrodes 42 to drive the resonator and sense the movement in the sensing direction due to the Coriolis effect, acceleration, deceleration and/or inclination force.

The vibrating resonator assembly 20 advantageously may produce a wine glass mode shape, namely, the common mode shape of ring vibratory gyroscopes. Since the anchor post 32 is fixed the, vibrating ring resonation assembly 20 *** operate substantially with flexural vibrations only, and whereby flexural mode shapes depend on the number of nodes. The driving and sensing axis flexural mode for ring resonator 20 of FIG. 2 preferably includes two modes, and wherein amplitude of the vibration modes determines the sensitivity of the MEMS gyroscope 10.

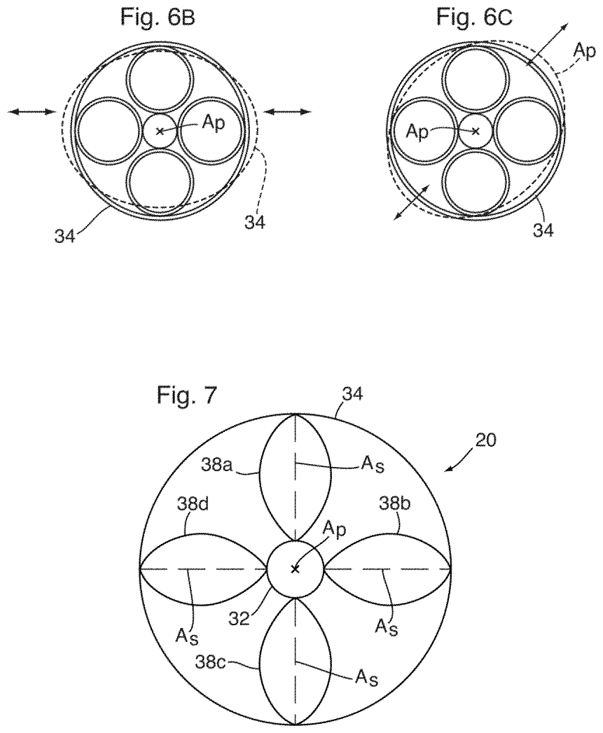

FIGS. 6a, 6b and 6c illustrate schematically the deformation of the outer ring 34 in deformation and oscillatory movement relative to the central anchor post 32 and electrodes 42a,42b,42c,42d under inertial forces. When the vibrating ring resonator assembly 20 is at rest, the ring supports 38a,38b,38c,38d each assume an undeformed circular configuration, and act in concert with the outer ring 34 to resiliently return the outer ring 34 to an undeformed circular configuration, concentric about and centered on the anchor post axis Aₚ.

In FIGS. 6a-6c, the wine glass mode shape of the vibrating ring resonator assembly 20 is shown. FIG. 6a illustrates the application of a minimum threshold force on the vibrating ring resonator assembly force and resulting deformation and radial motion on the outer ring 34. FIG. 6b shows schematically, in phantom, the deformation of the outer ring 34 under or drive flexural forces, wherein top and bottom side portions of the outer ring 34 are moved radially inward towards the axis Aₚ, relative to the outer ring 34 ends. FIG. 6c illustrates schematically the deformation and movement of the outer ring 34 in phantom, the under application of lateral and/or flexural forces.

In the embodiment shown in FIG. 2, the outer ring 34 is supported for deformable movement by the four-circular ring supports 38a,38b,38c,38d that are fixedly secured to the anchor post 32. The surrounding electrodes 42a-d are used for driving, sensing and signal generation. It is recognized that the cauliflower design of the vibrating ring resonator assembly 20 and the circular shape of the ring supports 38a-38d provides a further parameter, in addition to the thickness T and width W of the individual spring support sidewalls which allows for further control and adjustment of the overall stiffness of each “spring” 38, namely, radial diameter R, the of each spring support 38, and which determines the overall spring support 38 diameter. In particular, it has been recognized that the stiffness, shape of the spring supports 38 and the operating mode shapes of the ring resonator assembly 20 can be controlled by changing the ring size of the diameter of the ring-shaped spring support 20. The design of the ring resonator assembly 20 may increase the stiffness of the overall structure because the closed geometry of the spring supports 38 and their closed semi-circular arcs. This may allow for higher voltages to vibrate the outer ring 34 compared to conventional vibrating ring gyroscopes. In terms of fabrication, the release time of the present design may increase, because of the minimized gap spacing (Gₛ) space between the adjacent radial arcs which form the sides of each spring supports 38a,38b,38c,38d.

Estimates of the stiffness of a given spring support 38 may further be derived by mathematically modeling and compared to those of other designs to examine the effect of the spring design on resonance frequencies, vibration amplitude, and sensitivity of the vibrating ring resonator assembly 20. In the preferred construction of FIG. 2, four ring supports 38a,38b,38c,38d are provided which all have the same dimensions, and properties.

Each ring support 38 which form one of four cauliflower shaped spring support “petals”, has two symmetrical arcs, symmetrical about the support axis Aₛ. The stiffness of each spring support 38 can be calculated using the equation of stress analysis according to formulae (1):

$$Stress = σ = \frac{{M}_{y}}{I} \frac{h}{2} \qquad ( 1 )$$

M_{y} is the bending moment due to applied force (electrodes), l is the moment of inertia of the cross-section area, and h/2 is half of the cross-section area height, close to the neutral layer where the maximum stress is applied. Where the spring support 38 is provided with a sidewall having the moment of inertia can be calculated according to formulae (2):

$$I = \frac{{bh}^{3}}{12} \qquad ( 2 )$$

where b and h are the width (shown as T in FIG. 3) and height (shown as H in FIG. 4) of the cross-section area, respectively. The bending moment due to the applied force (electrical) can be calculated as accordingly to formulae (3):

$$M = F ( \frac{d}{2} ) \qquad ( 3 )$$

where F is the applied force due to the electrodes and d/2 is the moment where the maximum bending force occurs. By determining the above values, stress on each arc of the petal can be estimated as per formulae (4):

$$Stress = σ = \frac{{M}_{y}}{I} \frac{h}{2} = \frac{Fdh 12}{4 {bh}^{3}} \\ σ = \frac{3 Fd}{{bh}^{2}} \qquad ( 4 )$$

Then, the relationship between stress (σ), strain (ε), and Young modulus (E) can be invoked according to formula (5)-(8):

σ=Eε (5)

Compare both equations:

$$\frac{3 Fd}{{bh}^{2}} = E ε$$

Rearranging gives,

$$F = \frac{{Ebh}^{2}}{3 d} ε \qquad ( 6 )$$

Compare with Hooks Law,

F=kΔx=kε (7)

### Compare Equations 6 and 7

$$k = \frac{{Ebh}^{2}}{3 d} \qquad ( 8 )$$

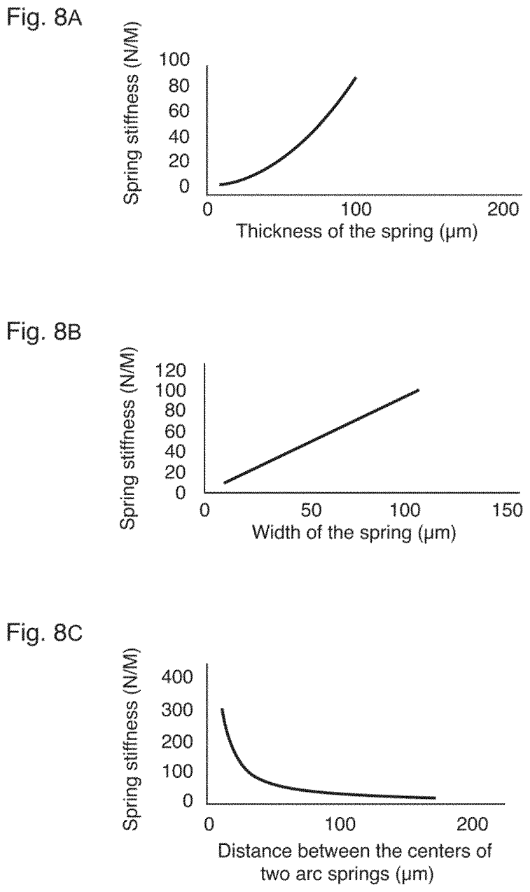

Each spring support 38 is defined by two semi-circular arcs which are symmetrical about the radial spring support axis A, and which join to form the closed geometry of the circular structure. The stiffness of one arc of the petal (FIG. 7) is k=10.65 N/m was calculated using a Young modulus (E) of 179 GPa, petal width of the spring support (b) of 10 μm, height or vertical thickness, h of 50 μm, and the distance between opposing centers of the two arcs (d) of 140 μm. The other opposing arc of the petal has the same stiffness (k=10.65 N/m). Therefore, the stiffness of each petal or spring support 38 is =2k(arc)=k, =21.3 N/m, and the total stiffness of all four spring supports 38a,38b, 38c, 38d=4kₚ=85.2 N/m. The calculated value is comparable to the support springs of other vibrating ring gyroscopes; the flexural mode stiffness of their design is K=70 N/m as illustrated in FIGS. 8(a)-8(c). The stiffness of the present design is expected to be high because of the closed arc or circular structure. The higher value provides a spring support 38 which is more rigid structure and is less sensitive to environmental noise.

The stiffness of the lens/petal and circular shaped spring supports 38 is also characterized by its lateral width, vertical thickness, and the center distance between the two arcs. Stiffness is shown to vary in linear and exponential proportion to the width and the thickness of the spring support 38, respectively. The center distance between the two arcs of the spring support 38 affects the deformability and spring stiffness in an inverse and exponential manner. It is recommended that this feature can be used to control the stiffness of the spring support without changing support width and thickness.

The performance of the MEMS gyroscope 10 may be impacted by the frequencies of driving and sensing modes, damping time, and quality factors. In general, when the vibrating outer ring 34 is excited with an electrical voltage, a driving vibration mode is achieved. Under a rotational effect, a Coriolis force is produced perpendicular to the direction of the driving mode, which causes a resultant vibrating mode or sensing mode at 45° to the driving mode (FIG. 6(a)). Matching two vibration modes is based on mechanical structure, Coriolis force, and acceleration. The Coriolis force is proportional to both the angular velocity of the rotating object and the linear velocity of the object moving toward or away from the axis of rotation. Under rotation, the Coriolis acceleration will cause energy to be transformed from the primary mode vibration amplitude to the secondary mode vibration amplitude.

The frequency of the vibrating ring resonator assembly 20 can be calculated using the general formula of natural frequency of formulae (9).

$${f}_{n} = \frac{1}{2 π} \sqrt{\frac{{k}_{eff}}{{m}_{eff}}} \qquad ( 9 )$$

where k_{eff} and m_{eff} are the effective stiffness and effective mass of the proposed structure, respectively.

The effective stiffness can be calculated according to formulae (10) as follows:

k_{eff}=kₛ+k_{ring} (10)

where kₛ is 85.20 N/m, derived at a width of 10 μm as noted above. The stiffness of the outer ring can be computed according to formulae (11),

$${k}_{ring} = \frac{EI}{{r}^{3}} = E \frac{{wt}^{3}}{12} \qquad ( 11 )$$

with a Young modulus (E) of 179 GPa, ring radius (r) of 0.6 mm, and moment of inertia of

$$I = \frac{{bh}^{3}}{12} .$$

The design parameters of the outer ring 32 are width (b), 10 μm, and thickness (h), 50 μm.

$${k}_{ring} = \frac{179 \times {10}^{9} \times 10 \times {10}^{- 6} \times {( 50 \times {10}^{- 6} )}^{3}}{12 {( 0.6 )}^{3}} = 86.32 N / m$$

Substituting values into formulae 10.

Effective stiffness=k_{eff}=85.20+86.32=171.52 N/m

### Effective Mass

Since the anchor post 32 is fixed, therefore, the effective mass can be computed as formulae (12)

m_{eff}=m_{ring}+m_{springs}

m_{eff}=ρ(V_{ring}+Vₛ) (12)

where ρ is the density of the ring 32 and ring supports 38 (single crystalline polysilicon),

$$2329 \frac{kg}{{m}^{3}}$$

The volume of the outer ring (V_{ring}) and ring supports (Vₛ) was calculated from the geometry using computational software COMSOL™ 5.5. The proposed design was developed in COMSOL™ and the volume of all four petal spring supports and the ring (FIG. 7) were measured with the software. For a width of 10 μm and a height (thickness) of 50 μm,

V_{ring}=0.00187×10⁻⁹ m³;Vₛ=0.00111×10⁻⁹ m³

Substituting values in formula 12,

m_{eff}=2329(0.001901×10⁻⁹+0.00111×10⁻⁹)

m_{eff}=7.0×10⁻⁹ kg

Finally, substituting the values of k_{eff} and m_{eff} into formula 9, we can obtain the natural frequency of the ring resonator assembly 20 (lens/petal shape spring resonator—FIG. 7) at a width of 10 μm:

$${f}_{n 10} = \frac{1}{2 π} \sqrt{\frac{171.52}{7 \times {10}^{- 9}}} = 24853 Hz = 24.85 kHz$$

The calculated natural frequency of the ring resonator assembly 20 is provided as estimate for the exemplary design, because mode shapes and the number of nodes were not considered in this calculation. The natural frequencies of a particular design will vary with final mode shape. Mode shapes with a higher number of nodes have higher natural frequency values and lower amplitudes. The calculated value of the natural frequency was compared with the computational natural frequency value by simulation of different mode shapes in COMSOL™.

### Mechanical Sensitivity

The sensitivity of the vibrating ring resonator assembly 20 can be defined by taking the ratio of the amplitude of secondary mode vibration to the amplitude of the primary mode vibration as according to formula 13):

$$\frac{{q}_{sense}}{{q}_{drive}} = 4 {A}_{ℊ} Q \frac{{Ω}_{z}}{ω} \qquad ( 13 )$$

Wherein, A_{g} is the angular gain constant, (which is assumed to be the same value (A_{g}=0.37) noted in “Greiff” a vibratory micromechanical gyroscope, supra; q_{drive} and qₛₑₙₛₑ are the vibration amplitudes of driving and sensing mode, respectively; Q is the quality factor; (the resonance frequency; and Ω_{z} the rotational velocity. The sensing axis is directly proportional to the rotational speed.

Formula 13 above can be arranged to determine mechanical sensitivity:

$${S}_{mech} = \frac{{q}_{sense}}{{Ω}_{z}} = 4 {A}_{ℊ} Q \frac{{q}_{drive}}{w} \qquad ( 14 )$$

From the basic equation of motion of an exemplary VRG 10 under excitation, the value of q_{drive} can be determined according to formulae (15) and (16),

$$\begin{matrix}{q}_{drive} = \frac{{F}_{Applied} Q}{{ω}^{2} m} = \frac{{F}_{Applied} Q}{{k}_{eff}} = \frac{{F}_{Applied} Q}{171.52} & ( {ω}^{2} m = k )\end{matrix} \qquad ( 15 )$$

where F_{Applied} is the applied force on the structure and Q is the quality factor. Since the applied force is based on applied voltage,

F_{Applied}∝applied voltage

F_{Applied}=KV_{Applied}(for simplicity in calculation,assume K=1)

F_{Applied}=V_{Applied} (16)

where V_{Applied} must be less than the pull-in voltage (Vₚ). The pull-in voltage of the exemplary design can be found with the following formulae (17) to (19):

$${V}_{p} = 2 \frac{{x}_{0}}{3} \sqrt{\frac{k}{1.5 {C}_{o}}} \qquad ( 17 )$$

where x₀=initial gap=10×10⁻⁶ m and k=effective stiffness=171.52 N/m

$${C}_{o} = \frac{ε . A}{d} \qquad ( 18 )$$

where ε=the permittivity constant=8.85×10⁻¹², A=the overlapping area, L×h, and L is the overlapping length between the electrode 42 and the outer ring 34,

$$\frac{n}{360} \times 2 π r .$$

Since the exemplary construction of FIG. 2 has four electrodes 42a,42b,42c,42d that substantially cover the complete outer ring 34, the angular displacement of each electrode 42 is approximately 90°, and the radius of curvature calculated from the geometry is 0.62 mm. Therefore, L is

$$L = \frac{90}{360} \times 2 π \times 0.62 = 0.9734 mm \qquad ( 19 )$$

with h=height (thickness) of the electrode=50×10⁻³ mm, A=overlapping area=L×h=0.9734×50×10⁻³=48.67 mm²=48.67×10⁻⁶ m². Substituting the appropriate values into Formula 18 results in

$$c = \frac{ε . A}{d} = \frac{8.85 \times {10}^{- 12} \times 48.67 \times {10}^{- 6}}{10 \times {10}^{- 6}} = 43. \times {10}^{- 12} F$$

Putting these values into Formula 17 gives

$${V}_{p} = 2 \frac{{x}_{0}}{3} \sqrt{\frac{k}{1.5 \times {C}_{o}}} = 2 \times \frac{10 \times {10}^{- 6}}{3} \times \sqrt{\frac{171.52}{1.5 \times 43. \times {10}^{- 12}}}$$

$${V}_{p} = 10.87 V$$

The calculated value of pull-in voltage is 10.87 V. Therefore, F_{Applied}<10.87 V.

To avoid the pull-in effect, consider F_{Applied}=10 V.
Therefore, q_{drive} is, using values from Formula 15,

$${q}_{drive} = \frac{{F}_{Applied} Q}{171.52} = \frac{10 Q}{171.52} = 0.0583 Q$$

and S_{mech}, using values from Formula 14,

$${S}_{mech} = 4 {A}_{ℊ} Q \frac{{q}_{drive}}{ω} = 4 \times 0.37 \times Q \frac{0.0583 xQ}{2 π \times 24.85 \times {10}^{3}} = 5.495 \times {10}^{- 7} {Q}^{2} \frac{V}{rad / sec}$$

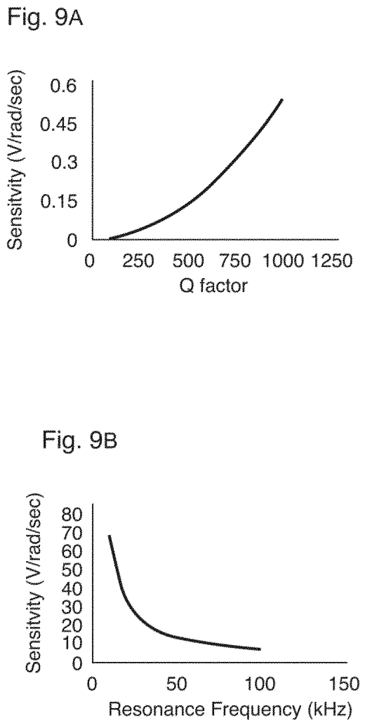

FIGS. 9(a) and 9(b) shows the effect of Q factor on the mechanical sensitivity of the design (FIG. 7). Sensitivity of the MEMS gyroscope 10 increases exponentially with Q factor as expected; therefore, it requires a high Q factor to achieve a large sensing amplitude. Since the vibrating ring resonator assembly 20 of FIG. 2 has symmetric features, the driving and sensing frequencies were expected to match, resulting in a large Q factor and increasing the sensitivity of the proposed gyroscope. FIG. 9(b) shows the effect of resonance (natural) frequency on mechanical sensitivity at a constant Q factor of 1000 of the lens/petal springs support (FIG. 7): sensitivity exponentially decreased with increase in natural frequency. To validate the numerical results, a simulation model was developed in COMSOL™ to determine the natural frequencies at different mode shapes. The best values of design parameters were selected in the next section using COMSOL simulation software.

The construction shown in FIG. 2 and its characteristics, including mode shapes, natural frequencies, and outer ring 34 and spring supports 38, wall thickness and width allow for more precise optimization before fabrication. Therefore, the ring resonator assembly 20 may be modeled using COMSOL 5.5™ or other suitable software, and simulations used to assess ranges of the design parameters to find the optimal of natural frequency values.

A mesh independent test was additionally performed with a selected mesh size (0.02) considered in the mesh independent test. The initial boundary conditions were such that the anchor post 32 was fixed while remaining parts of the structure the spring supports 38 and outer ring 34 were permitted free.

In the frequency analysis, the specific vibration patterns (modes of vibration) of the assembly 20 were observed. The simulation showed that the outer ring 34 vibration has mode shape frequencies—with 0 Hz frequency splitting—of 27.06 kHz (two nodes) and 41.08 kHz (three nodes) at a width of 10 μm of the lens/petal spring design (FIG. 7). The calculated value of the natural frequency of the lens/petal spring support resonator is 24.8 kHz, comparable to the two-node frequency of 27.06 kHz. The small difference was expected, because no mode shape and number of nodes were considered in the calculation of natural frequency. The calculated natural frequency may be associated with the mode shape of a lower number of nodes (n=1). In-plane and out-plane vibration could also have contributed to this difference, since the simulation model was restricted to produce only in-plane vibration to ensure the desired mode shape (wine glass mode shape), while no such restriction was applied in the numerical calculation of frequency.

The design parameters of the ring resonator assembly 20 were also estimated using COMSOL™ to produce the desired mode shape at mode match frequency. In plane vibration mode, the natural frequency does not appear to be significantly affected by the thickness of the structure (outer ring 34 and ring supports 38) at a constant width. Natural frequency changes significantly with the width of structure at constant thickness. The range of mode match frequencies resulting from changes in the width of the structure (outer ring and

petals) at a constant thickness (50 μm) of the lens/petal spring design (FIG. 7) is shown in Table 1.

Table 1 illustrates that, at constant thickness, the resonance frequency changes significantly with the variation of the width of the structure. An average difference of 15 kHz is observed when the width of the spring supports is varied by 10 μm. For higher performance and higher sensitivity, a low natural frequency is desirable, as shown in FIG. 8(b). Therefore, spring support width and outer ring were varied only up to 30 μm to obtain a reasonable range of mode match frequencies at n=2 and 3, as shown in Table 1.

TABLE 1
Results of simulation of the present design with different structure widths.
Variation of width at constant thickness (50 μm)

| | Structure width | | | | | |
|---|---|---|---|---|---|---|
| | Spring | Outer | Resonance Frequencies in kHz | | | |
| | Support | Ring | | N = 2 | | N = 3 |
| Design | width | width | | (degenerate | | (degenerate |
| # | (μm) | (μm) | N = 2 | mode) | N = 3 | mode) |
| 1 | 10 | 10 | 27.06 | 27.06 | 41.08 | 41.08 |
| 2 | 20 | 10 | 25.46 | 25.46 | 49.20 | 49.20 |
| 3 | 20 | 20 | 38.23 | 38.23 | 55.61 | 55.61 |
| 4 | 30 | 20 | 51.91 | 51.91 | 80.67 | 80.67 |
| 5 | 30 | 30 | 52.70 | 52.70 | 82.12 | 82.12 |

To ensure a stable structure test, design #4 (spring support width=30 μm and outer ring width=20 μm) was considered for fabrication. The final design was scaled down (90%-70% to the original size) to allow production of more prototypes at different scales. The results of simulation of the scaled-down version of the final design at a constant thickness of 80 μm (equivalent to the thickness of prototype device layer) are shown in Table 2.

TABLE 2
Simulation results of the scaled-down design (for a constant thickness of 80 μm)

| | Anchor | Outer | Spring | Outer | Computed resonance frequencies (kHz) | | | |
|---|---|---|---|---|---|---|---|---|
| | Post | Ring | Support | Ring | | N = 2 | | N = 3 |
| | diameter | diameter | width | width | | (degenerate | | (degenerate |
| Prototype | (μm) | (μm) | (μm) | (μm) | N = 2 | mode) | N = 3 | mode) |
| 1 | 200 | 1200 | 30 | 20 | 51.91 | 51.91 | 80.67 | 80.67 |
| 2 | 180 | 1080 | 27 | 18 | 57.69 | 57.69 | 89.17 | 89.17 |
| 3 | 160 | 960 | 24 | 16 | 64.89 | 64.89 | 100.84 | 100.84 |
| 4 | 140 | 840 | 21 | 14 | 74.32 | 74.32 | 152.30 | 152.30 |

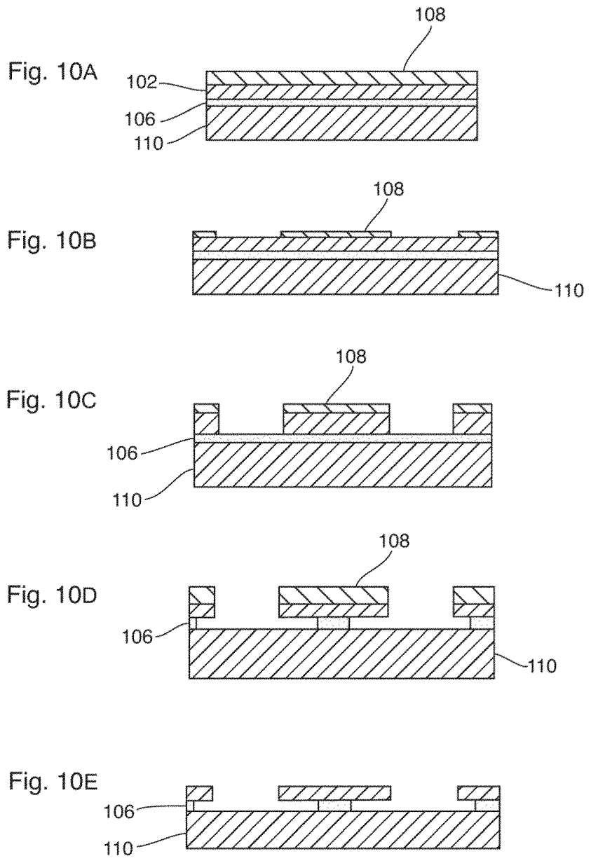

Finally, all scaled-down designs of the prototypes (1-4) were considered for fabrication. Using the similar approach, simulation result shows a degenerate mode shape resonance frequency at n=2 of the ring spring resonator (FIG. 2) was achieved at 248 kHz. FIGS. 10a-10e illustrate schematically a process for the photo resist deposition manufacture of the outer ring 34, spring supports 38a,38b,38c,38d and central anchor post 32 used in the vibrating ring resonator assembly shown in FIG. 2 and FIG. 7.

Scaled-down designs were considered for fabrication on a single wafer using a standard surface micromachining process. Since the vibrating ring resonator assembly 20 has a fixed anchor post 22 to hold both the spring supports 38a,38b,38c,38d and outer ring 32 cantilevered as a suspended structure, namely with a four petal spring support 38 array and outer ring 34—a silicon on insulator (SOI) wafer has 102 silicon layer of 80 μm, with a device layer 104, of 500 μm thickness and an oxide insulation layer 106, and a photoresist top layer 108 was used for prototype fabrication. In the SOI wafer, the oxide under the anchor post 32 connects to a silicon substrate 110. The oxide keeps the anchor post 32 fixed, while the spring supports 38 and outer ring 34 arc suspended after the etching process. The exemplary fabrication process is shown schematically.

A recipe was developed for dry etching the device layer thickness including the integral outer ring 34, spring supports 38a-38d and position of the anchor post 32 to the oxide layer 106 using plasma gas. The thickness of the pattern up to 80 μm was measured using an optical microscope. In a next step, wet etching using IF (49%) removed the oxide layer 106 underneath the suspended outer ring 34 and spring supports 38 structures. Wet etching was performed on a timed basis to both release the suspended structures and to develop the remaining oxide anchor post 32. Different samples with different timing were developed to ensure the anchor post 32 would remain attached to the substrate 110, while the remaining outer ring 34 and spring support 38 structures were suspended. Suitable time for wet etching was found to be around eight minutes, allowing safe release of the structure, without loss of the anchor post 32 attachment to the substrate.

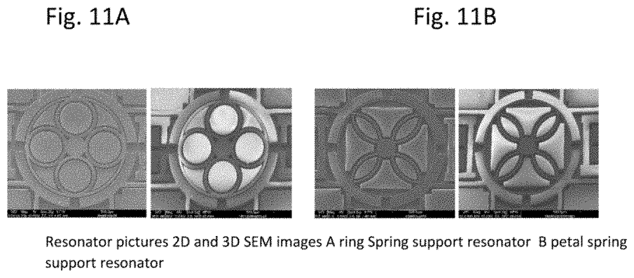

FIGS. 11a and 11b, show SEM images of the resonators showed the outer ring and spring supports of ring spring and lens/petal spring respectively, and a 10 μm spacing between the outer ring and the radially spaced electrodes visible. The thickness of the prototype structure was measured using a Nikon digital scope and was found to be 80 μm at the suspended components. These images and measurements indicate the customized fabrication process was carried out successfully and that the etching approach worked well for prototype

Prototype testing of a scaled-down to 80% of an actual size vibrating ring resonator performed inside a probe station. The chip was connected with probes: the anchor was grounded with one probe and the electrodes connected to others (via a pad) to receive AC signals. A function generator (DG4102) was used to provide arbitrary sine waves from a frequency range of 5 to 80 kHz to test the chip at a resonance frequency. A motion-induced current was produced under harmonic excitation due of electrostatic actuation of the chip. The output frequency and the motion-induced current were measured with a lock-in amplifier (HF2LI) and a spectrum analyzer (Agilent N9010A).

Since the resonator vibrating ring is surrounded by driving and sensing electrodes, a safe range of voltage and frequency will be applied to the driving electrodes. The displacement of the vibrating ring can be measured by changing the capacitance between the vibrating ring and the sensing electrodes; change in capacitance can be easily measured electronically using a signal conditioning circuit. For the gyroscope, angular (rotational) velocity can be determined by measuring the Coriolis force, which is dependent on the distance in the direction of Coriolis force.

A prototype MEMS resonator was designed and fabricated with petal and circular ring-shaped spring supports 38. The stiffness of the support ring (petal spring) supports was calculated mathematically and compared to other types of ring gyroscopes. The higher stiffness of the present design results in a structure more rigid, durable, and less sensitive to environmental noise, distance between the center of two arcs forming each side of the spring support 30 controlling the stiffness of the gyroscope and the mode shapes of the structure. In the prototype construction, the natural frequency of the ring resonator 20 was selected at 24.8 kHz, comparable to the simulated frequency of 27 kHz. Since the mode shapes and the number of nodes were not considered in the calculation, a difference of 2.2 kHz was observed between the calculated and simulated natural frequencies.

The design parameters of mode match frequencies were also considered and the best values for the design parameters estimated using COMSOL™ simulation software. The results of simulation showed that the natural frequencies are dependent on the width of the structure, but independent of its thickness. In selected prototype design with a spring support width 30 μm and outer ring width 20 μm was scaled down into four prototypes for fabrication.

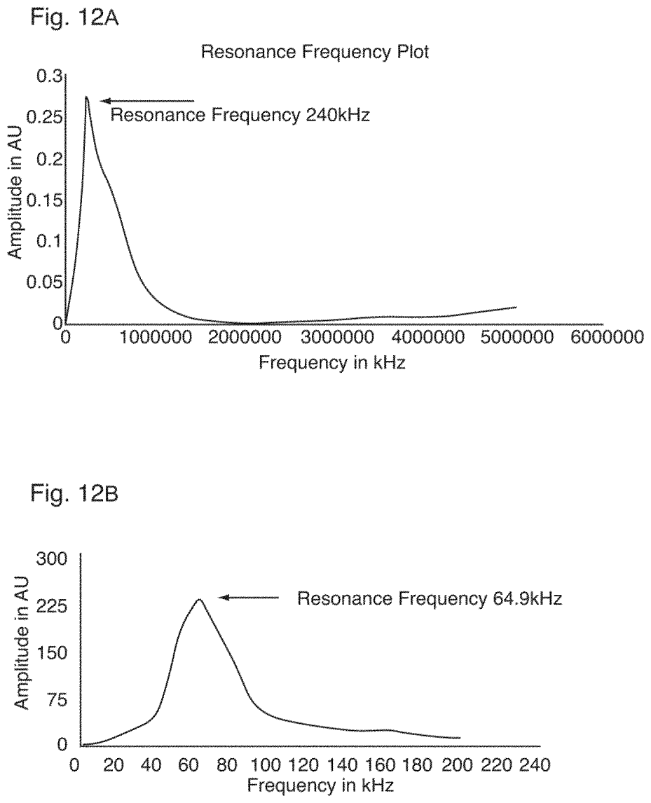

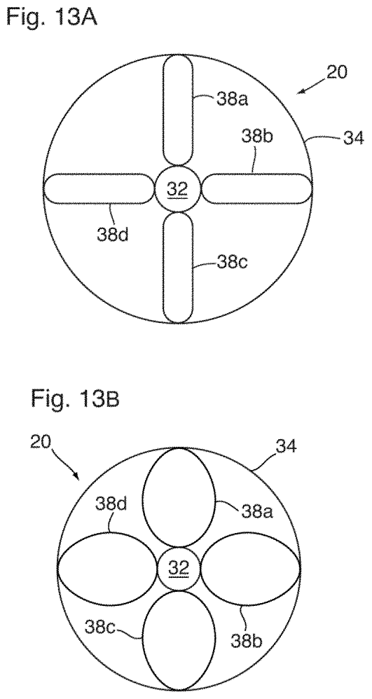

Fabrication was performed in a cleanroom using a standard surface micromachining process. Prototype 3 (petal spring resonator) and ring spring resonator were tested on a probe station using arbitrary sinusoidal signals and the results recorded using a lock-in amplifier and spectrum analyzer. The results in FIGS. 12a and 12b show that the experimental resonance frequency of the ring spring resonator (FIG. 2) and petal spring resonator (FIG. 7) are 240 kHz and 64.9 kHz, respectively close with the simulated natural frequency of 248 kHz (ring resonator) and 64.98 kHz (petal resonator) for a mode shape with two nodes.

Although FIG. 2 illustrates the vibratory ring resonator assembly 20 as including four circular ring-shaped spring supports 38a,38b,38c,38d, the invention is not so limited. In alternative constructions, fewer or greater numbers of spring supports 38 may be provided.

Although circular ring-shaped spring supports 38 advantageously facilitate the modeling and premanufacture of vibrating ring resonator assemblies according to mathematical modeling, the invention is not so limited. It is to be appreciated that spring supports having other geometric shapes, and more preferably other closed geometric shapes could also be used to FIGS. 13A and 13B which illustrate schematically, vibrating ring resonator assemblies 20 in accordance with alternative constructions, and wherein like reference numerals are used to identify like components.

In FIG. 13A, the vibrating ring resonator 20 is provided with four spring supports 38a,38b,38c,38d which are oval shaped, and which extend longitudinal and symmetrically about respective radial spring axis Aₛ.

FIG. 13B illustrates the vibrating ring resonator ring assembly 20 as incorporating four parabolic shaped spring supports.

Although the detailed description describes the vibrating rings resonator assembly as including four identical configured spring supports 38, the invention is not so limited. In other constructions, the vibrating ring resonator may be provided with fewer or greater numbers of individual spring supports. Most preferably, the vibrating ring resonator assembly will be provided with an even number of four, six, eight or ten spring supports 38. Other constructions are, however, possible.

In addition, in differing embodiments, different spring supports 38 having different geometric shapes may be combined together in a single ring resonator assembly 20.

Although the detailed description describes and illustrates various preferred embodiment, the invention is not so limited. Many modifications and variations will now occur to persons skilled in the art. For a definition of the invention, reference may be had to the appended claims.

We claim:

1. A vibrating ring resonator assembly comprising,
a central support anchor having an anchor axis,
an annular outer ring member,
at least one electrode structure spaced radially about at least part of the outer ring member,
a plurality of resiliently deformable spring supports supporting said outer ring member in oscillatory and/or deformation movement relative to said central anchor and said at least one electrode structure, whereby movement of the outer ring member relative to said at least electrode is structure is configured to generates an electrical signal,
the spring supports configured to resiliently bias said outer ring to return to substantially circular undeformed geometry concentric with said anchor axis under forces selected less than predetermined threshold force.

2. The ring resonator assembly as claimed claim 1, wherein said predetermined threshold force is comprised of at least one force selected from the group consisting of a Coriolis force, acceleration force, force component, a deceleration force component, and a gravitational force component.

3. The ring resonator assembly as claimed in claim 1, comprising between three and twenty, and more preferably between four and eight of said spring supports, each of said spring supports radially oriented spring support axis, the support axis being disposed at substantially equally radially spaced locations about said anchor axis.

4. The ring resonator assembly as claimed in claim 1, wherein said spring supports having a substantially closed geometric shape symmetrically formed about said associates spring support axis.

5. The ring resonator assembly as claimed in claim 4, wherein said closed geometric shape selected from the group consisting of a circle, an oval, a parabola and a vesica piscis.

6. The ring resonator assembly as claimed in claim 4, wherein said spring supports comprise circular spring supports having a radial diameter selected at between about 0.2 and 0.4 times the radial diameter of the outer ring members.

7. The vibrating ring resonator assembly of claim 5, wherein each of the spring supports span radially from the central anchor to an inner peripheral surface of the outer ring member, integrally formed.

8. The vibrating ring resonator assembly of claim 7, wherein each of the spring supports have a thickness (height) selected at between about 5 and 100 microns, preferably between 30 and about 80 microns, and a width of between about 10 and 30 microns and preferably about 10 and 20 microns.

9. The vibrating ring resonator assembly as claimed in claim 8, wherein said outer ring member has a thickness (height) selected at between about 10 and 100 microns, preferably between 30 and about 80 microns, and a width of between about 10 and 30 microns and preferably about 10 and 20 microns.

10. A gyroscope ring resonator comprising,
a ring resonator including,
a central support having a support axis,
an outer ring member disposed radially about the support axis, the outer ring member having an outer peripheral surface and an inner peripheral surface spaced radially towards the support axis,
a plurality of spring supports interposed between said central support and said inner peripheral surface, the spring supports comprising a closed geometric body and supporting said outer ring member in at least one of oscillatory and deformable movement relative to said central support, whereby the application of a predetermined threshold force,
the outer ring member being configured for movement from a rest orientation extending concentrically about said support axis with a substantially constant radial distance from said support axis, and a deformed orientation wherein portions of the outer ring member are moved to differing radial distances from said support axis, the spring supports resiliently biasing the outer ring member towards the rest orientation.

11. The gyroscope ring resonator of claim 10, wherein the spring supports are resiliently deformable and have a geometric shape selected from the group consisting of a circle, an oval, a parabola and a Vesica piscis/lens/petal, each spring support symmetrically formed about an associated radially extending axis, the spring axis being disposed at substantially equally spaced locations radially about the support axis.

12. The gyroscope ring resonator of claim 11, further comprising at least one electrode assembly extending radially about and spaced from a portion of said outer peripheral surface, and wherein deformable and/or oscillatory movement of said outer ring member between said rest and deformed orientations is selected to effect the generation of electric signals by the electrode assembly, and wherein the predetermined threshold force includes one or more of a Coriolis force, an acceleration force component, a deceleration force component and a gravitational force component.

13. The gyroscope ring resonator of claim 12, wherein said at least one electrode assembly includes an electrode having proximate surface spaced from and having a curvature substantially corresponding to a curvature of the outer peripheral surface when said outer ring is in said rest position.

14. The gyroscope ring resonator of claim 10, wherein the spring supports comprise circular spring supports, and the ring resonator comprises 4, 5, 6, 7, or 8 of said spring supports.

15. The gyroscope ring resonator of claim 13, wherein said spring supports are spaced radially about said central support and extend from said central support to said inner peripheral surface in a substantially coplanar orientation with said outer ring member, said outer ring and said spring supports being integrally formed.

16. The gyroscope ring resonator of claim 15, wherein said outer ring member has a radial thickness (height) selected at between about 10 and 100 microns, preferably about 30 and 80 microns, and a width of between about 10 microns and 30 microns, preferably between about 20 microns and 10 microns.

17. The gyroscope ring resonator of claim 16, wherein the gyroscope is a MEMS gyroscope comprises four said spring supports, the spring supports being substantially circular and having a radial diameter selected at between about 0.2 and 0.4 times a radial diameter of the outer ring member.

18. The gyroscope ring resonator of claim 16, wherein the inner spring supports are circular ring supports having substantially the identical ring diameter and/or substantially identical ring thickness and/or substantially identical ring vertical height.

19. A vibrating ring resonator assembly comprising:
a support anchor having a central anchor axis,
a circular outer resonator ring having an outer peripheral surface and an inner peripheral surface,
an electrode structure disposed radially outwardly from a least part of the outer peripheral surface from four to eight spring supports coupling the outer resonator ring to the support anchor, the spring supports spanning radially from the support anchor to the inner peripheral surface and having a substantially closed geometric shape selected from the group consisting of a circle, an ellipse, an oval and vesica piscis/lens/petal,
each spring support being symmetrical about an associated radially extending spring axis, the spring axis of the spring supports being disposed at substantially equally spaced locations about the central anchor axis, and
wherein the spring supports support the outer resonator ring in deformable and/or oscillatory movement relative to said electrode structure on the application of a threshold force.

20. The vibrating ring resonator assembly as claimed in claim 19, wherein said spring supports have a resiliently deformable circular closed geometric shape, on the application of the threshold force, the outer resonator ring being movable from a rest orientation wherein said outer peripheral surface is spaced concentrically a substantially constant distance from central anchor axis, to a deformed and/or displaced position, with portions of the outer peripheral surface moved different radial distances from the axis, the spring supports resiliently biasing the outer resonator ring towards the rest orientation.

21. The vibrating ring resonator assembly as claimed in claim 20, wherein said predetermined threshold force comprises at least one force component selected from the group consisting of a Coriolis force, comprising an acceleration force component, a deceleration force component, and a gravitational force component.

22. The vibrating ring resonator assembly as claimed in claim 20, wherein each of the spring supports have a thickness selected at between about 10 and 100 microns, preferably between 30 and about 80 microns, and a height of between about 10 and 20 microns and preferably about 10 and 20 microns; and
wherein the outer resonator ring has a height thickness selected at between about 10 and 100 microns, preferably between 30 and about 80 microns, and a width of between about 10 and 30 microns and preferably about 10 and 20 microns.

23. The vibration ring resonator assembly as claimed in claim 22, wherein the spring supports have a radial diameter selected at between about 0.2 to 0.45, preferably 0.3 to 0.4 times a radial diameter of the outer resonator ring.
